(19) United States
(12) Patent Application Publication
(10) Pub. No.: US 2007/0126052 A1
(43) Pub. Date: Jun. 7, 2007

(54) Method and apparatus for strapping the control gate and the bit line of a MONOS memory array

(75) Inventors: Harry Luan, Saratoga, CA (US); J.C. Young, Milpitas, CA (US); Arthur Wang, San Jose, CA (US); K.C. Chou, San Jose, CA (US); Kenlin Huang, Fremont, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Winbond Electronics Corporation America, San Jose, CA (US)

(21) Appl. No.: 11/292,941

(22) Filed: Dec. 1, 2005

(51) Int. Cl. H01L 29/792

(52) U.S. Cl. 257/324

(57) ABSTRACT

A method of manufacturing a non-volatile semiconductor memory. The method includes forming a word gate poly layer on a substrate, wherein an upper surface of the substrate defines a plane of the substrate. The method also includes forming a first dielectric layer coupled to the word gate poly layer and patterning the word gate poly layer and the first dielectric layer to form an array of word gate structures. The method further includes forming a poly plug layer and patterning the poly plug layer to form a plurality of poly plugs surrounded in the plane of the substrate on three sides, forming a plurality of control gates, forming a second dielectric layer, planarizing the second dielectric layer using a chemical-mechanical polishing process, and depositing a metal layer to provide electrical contact to the word gate structures.

### BACKGROUND OF THE INVENTION

The present invention relates generally to integrated circuit devices. More particularly, the invention provides a method and structure for a non-volatile memory device, commonly called a metal oxide-nitride-oxide on silicon (“MONOS” ) memory device. Merely by way of example, the present invention provides a method and apparatus for strapping both bit lines and control gates of a memory array with buried n⁺ bit lines. But it would be recognized that the invention has a much broader range of applicability.

Integrated circuits have proliferated through the years. Certain types of integrated circuits include memory devices. These memory devices include volatile memories such as dynamic random access memory devices, commonly called “DRAMs” and non-volatile memory devices. Non-volatile memory device are often capable of storing data when the power supply is turned off. An example of a non-volatile memory device is a Flash Memory Device. The Flash Memory Device includes a silicon floating polysilicon gate that stores electrical charges in the floating gate. Electrons are injected into the floating gate by channel hot electrons to program the Flash Memory Device. Such electrons are removed from the floating gate by a tunneling influence between the floating gate and the substrate. Other types of non-volatile memory devices also exist.

Another example of a non-volatile memory device is a Metal Oxide Nitride Oxide Silicon memory, which is commonly termed a “MONOS” memory. The MONOS memory includes a metal oxide silicon (MOS) transistor in which the gate dielectric is a composite oxide-nitride-oxide (ONO) layer. Electrons are introduced by hot electron injection into the ONO gate dielectric and stored in trap states in the silicon nitride layer of the ONO gate dielectric to program the device. The electrons are removed from the traps by a tunnel-assisted hot hole injection process. In a certain type of MONOS memory, the electrical charges are stored in traps separately at each of the edges of the transistor gate, resulting in two bits of storage in a single memory transistor.

An improved MONOS memory device incorporates two additional control gates, i.e., one at each side of the transistor gate. An example of such an improved MONOS device is shown in FIG. 1, which is a two bits per cell twin MONOS memory device proposed by Halo LSI Design & Device Technology, Inc. As can be seen in FIG. 1, memory cell 100 includes two control gates 20 and 30 formed on either side of the word gate 14. Insulating layer 24 separating control gate 20 from the word gate 14 and the substrate is an ONO layer. As described above, charge storage is performed using this ONO layer of the memory device. Another insulating layer 26 separates control gate 30 from the word gate 14 and the substrate.

Other integrated circuit device elements are also illustrated in FIG. 1, including wordline polysilicon (poly) 50, wordline tungsten silicide 52, and insulating layer 54 formed using a high density plasma process. Control gate channel implant 60, control gate implant 62, with a lightly doped drain (LDD), and buried bitline implant region 64 are also illustrated in FIG. 1.

As illustrated in FIG. 1, impurity layers form the source and drain regions of this memory device. Two MONOS elements (TwinMONOS) are formed in memory device 100 and are controlled separately by control gates (CGs) 20 and 30. The TwinMONOS device also includes word gate and buried bit line implants. Generally, lithographic processes control the size of the stitch area, in which bit lines and control gates are stitched together. In some TwinMONOS designs, reductions in the stitch area are determined by the pitch of the bit lines and control gate geometries. From the above, it is seen that an improved technique for processing semiconductor devices is desired.

### SUMMARY OF THE INVENTION

According to the present invention, techniques directed to integrated circuit devices are provided. More particularly, the invention provides a method and structure for a non-volatile memory device, commonly called a metal oxide-nitride-oxide on silicon (“MONOS”) memory device. Merely by way of example, the present invention provides a method and apparatus for strapping both bit lines and control gates of a memory array with buried n⁺ bit lines. But it would be recognized that the invention has a much broader range of applicability.

According to an embodiment of the present invention, a method of manufacturing a non-volatile semiconductor memory is provided. The method includes forming a word gate poly layer on a substrate, wherein an upper surface of the substrate defines a plane of the substrate. The method also includes forming a first dielectric layer coupled to the word gate poly layer and patterning the word gate poly layer and the first dielectric layer to form an array of word gate structures. The method further includes forming a poly plug layer and patterning the poly plug layer to form a plurality of poly plugs surrounded in the plane of the substrate on three sides, forming a plurality of control gates, forming a second dielectric layer, planarizing the second dielectric layer using a chemical-mechanical polishing process, and depositing a metal layer to provide electrical contact to the word gate structures.

According to another embodiment of the present invention, a MONOS memory array is provided. The MONOS memory array includes an array of paired word gates disposed on a surface of a substrate. Each of the paired word gates includes an interior portion and two opposing side portions. The MONOS memory array also includes an ONO stack coupled to the array of paired word gates. The ONO stack covers the interior portion and the two opposing side portions of each of the paired word gates. The MONOS memory array further includes an array of word gate slots disposed between the interior portion and the two opposing side portions of the paired word gates and an array of poly plugs. Each of the poly plugs is formed in a word gate slot and coupled to the ONO stack on three sides.

Numerous benefits are achieved using the present invention over conventional techniques. Some embodiments provide MONOS memory arrays with stitch areas reduced by about 25%. Other embodiments of the present invention provide increased reliability CG contacts as the word line/control gate poly plug contact area is larger than that provided by conventional designs. In some embodiments, product yield is improved through the reduction in the number or elimination of submicron lithographic features. Depending upon the embodiment, one or more of these benefits may exist. These and other benefits have been described throughout the present specification and more particularly below.

### BRIEF DESCRIPTION OF THE DRAWINGS

FIG. 1 is a simplified cross-sectional view diagram of a conventional twin MONOS device;

FIG. 2 is a simplified schematic illustration of a conventional 3×6 MONOS array;

FIG. 3A is a simplified schematic illustration of an array stitching architecture according to an embodiment of the present invention;

FIG. 3B is a simplified schematic top view diagram illustrating various layers of a memory array according to an embodiment of the present invention;

FIGS. 4 through 10 are simplified drawings illustrating a method of fabricating a non-volatile memory array according to embodiments of the present invention;

FIGS. 11A and 11B are simplified cross-sectional view diagrams of a resulting structure according to an embodiment of the present invention;

FIGS. 12A through 12D are simplified top view diagrams illustrating various layers of a memory array according to an embodiment of the present invention; and

FIG. 13 is a simplified flow diagram illustrating a method of fabricating a memory array according to an embodiment of the present invention.

### DETAILED DESCRIPTION OF SPECIFIC EMBODIMENTS

According to the present invention, techniques directed to integrated circuit devices are provided. More particularly, the invention provides a method and structure for a non-volatile memory device, commonly called a metal oxide-nitride-oxide on silicon (“MONOS”) memory device. Merely by way of example, the present invention provides a method and apparatus for strapping both bit lines and control gates of a memory array with buried n⁺ bit lines. But it would be recognized that the invention has a much broader range of applicability.

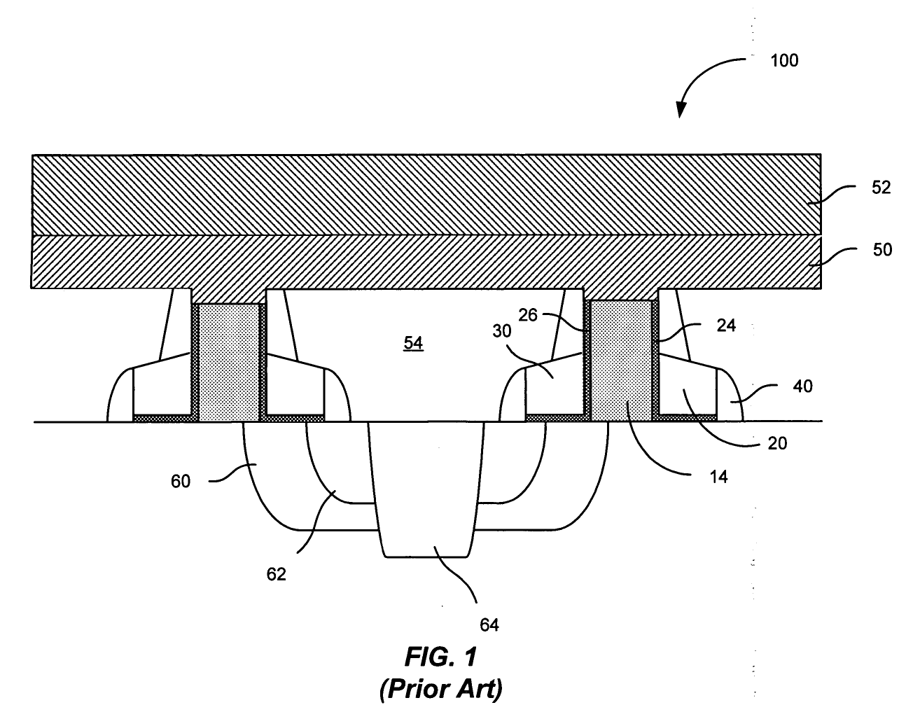

In the TwinMONOS flash memory illustrated in FIG. 1, the control gate (CG) is generally formed by a self-aligned side-wall (SW) spacer process. Generally, this SW polysilicon (poly) spacers 20 and 30 have a thickness of about 400 Å to about 700 Å and a height of about 1300 Å to about 2,000 Å. For this structure, the resulting CG poly resistance is generally in the range of about 4 kΩ to about 6 kΩ per micron of length. Accordingly, to achieve desired memory access speeds the CGs are strapped using a strapping period of a predetermined number of word lines. Because of similar resistance issues, bit lines formed by a buried diffusion process are also strapped to reduce RC loading. As will be evident to one of skill in the art, such strapping affects both read and write operations.

According to embodiments of the present invention, metal strapping of both the control gates and bit lines is accomplished through the use of contacts and vias to provide electrical contact to control gate poly and n⁺diffusion pickups. In some designs provided by embodiments of the present invention, control gates and bit lines for TwinMONOS structures run in parallel, so metal stitching using alternating conducting films is utilized to provide preferred metal pitch spacings for a particular semiconductor processing technology. According to some embodiments of the present invention, stitches are provided uniformly across the array. In some embodiments such uniformity is provided through mirror or translational symmetry of the stitched segments. In additional embodiments, transfer contacts and conductive local interconnects are provided with reduced electrical resistance. In other embodiments, the stitch area overhead is reduced to a predetermined value.

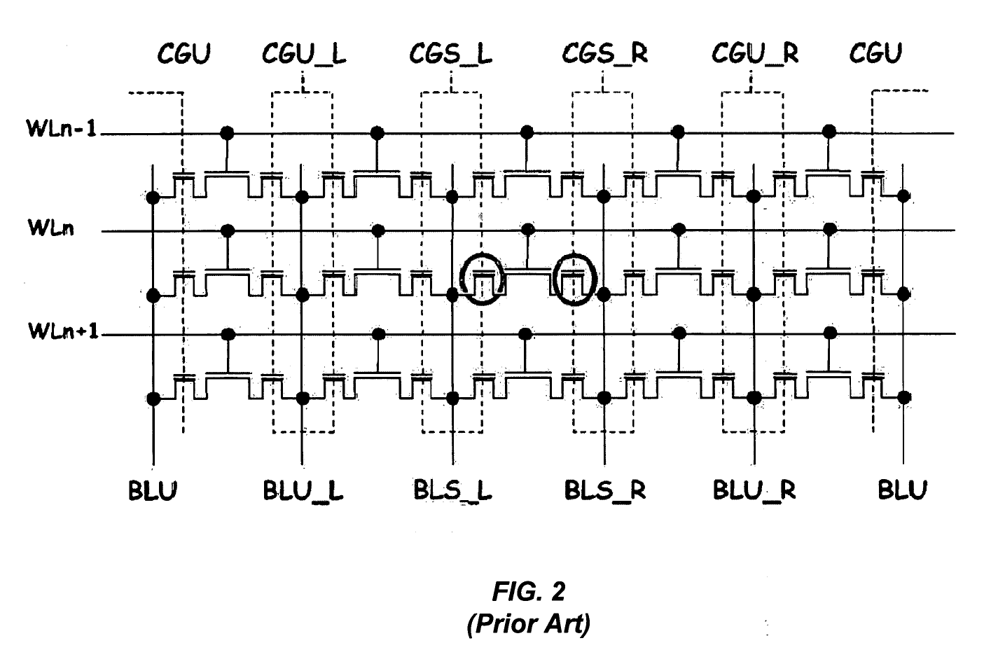

FIG. 2 is a simplified schematic illustration of a conventional 3×6 MONOS array. As illustrated in FIG. 2, the memory array includes a number of word lines (WLs) in the x-direction and a number of bit lines (BLs) and control gates (CGs) in the y-direction. As further illustrated in FIG. 2, bit lines are fabricated from n⁺ diffuision regions without contacts. Control gates are laid out vertically and are fabricated from a self-aligned sidewall polysilicon process. Word lines n−1 through n+1 are arranged horizontally in contact with a series of word gate islands, which service select transistors.

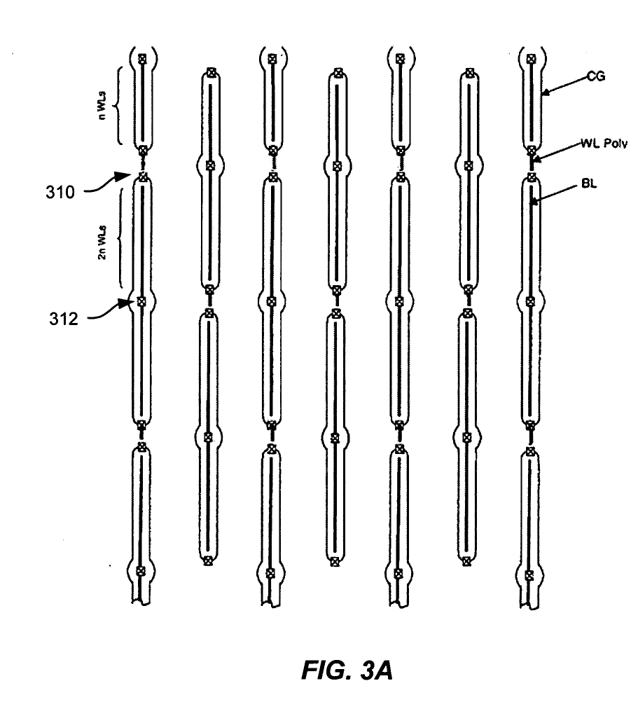

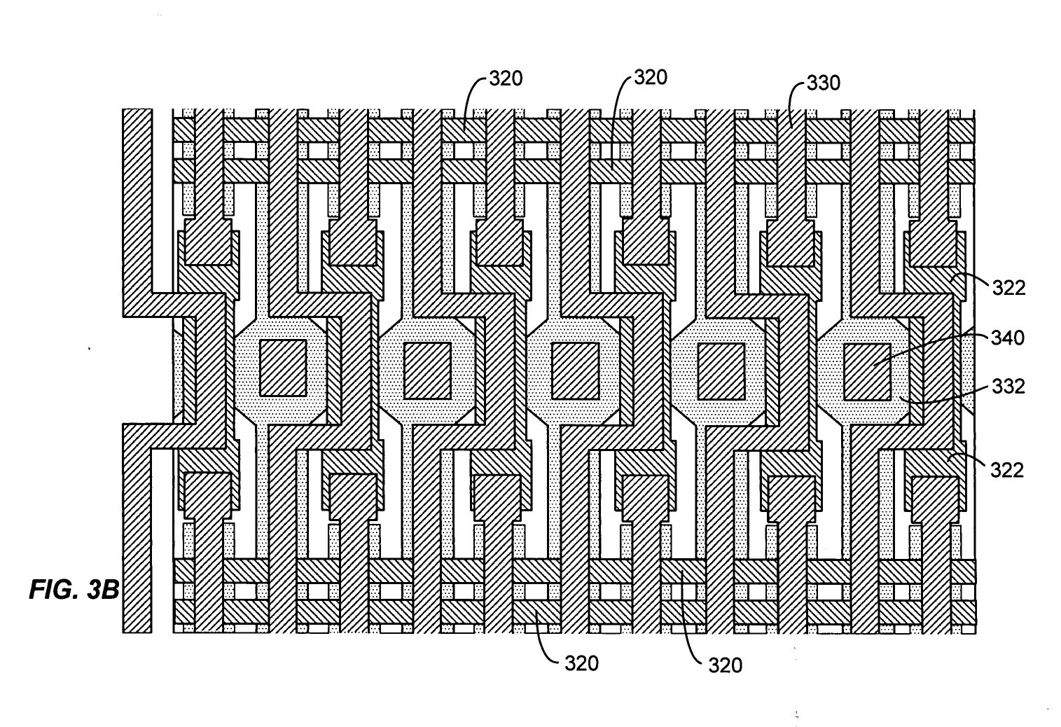

FIG. 3A is a simplified schematic illustration of an array stitching architecture according to an embodiment of the present invention. As illustrated in FIG. 3A, each column represents CGs fabricated using the self aligned sidewall poly process and BLs fabricated by n⁺ diffusion. A predetermined number of WLs, for example, n WLs, are provided between adjacent contacts to poly plugs. Depending on the application, the value of n varies between 8 and 64. Accordingly, 2n WLs are provided in between contacts 310 and 312 as illustrated in FIG. 3A. As described in additional detail below, for each column, CGs and BLs are contacted by metallization layers.

FIG. 3B is a simplified schematic top view diagram illustrating various layers of a memory array according to an embodiment of the present invention. In the portion of the memory array illustrated in FIG. 3B, WLs 320 are illustrating as running horizontally in the figure. Although only four WLs are illustrated in FIG. 3B, as discussed in relation to FIG. 3A, a predetermined number of WLs are provided according to embodiments of the present invention, the predetermined number generally being greater than four. Word line (WL) polysilicon (poly) 322 is provided to strap adjacent WGs. A metal-1 layer (M−1) 330 is provided for strapping of CGs. Layer 332 is n⁺ active BLs, which is tapped by contact (not shown), metal pad 340, via-1 (not shown), and metal-2 (not shown) running in the same vertical direction as M−1.

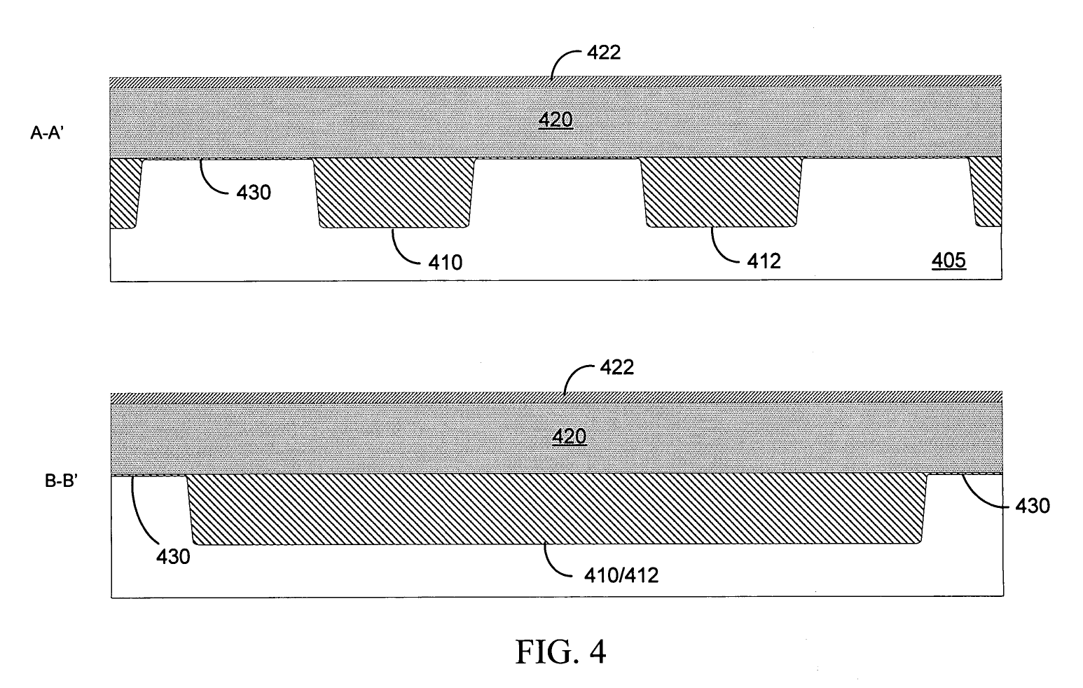

FIGS. 4 through 10 are simplified drawings illustrating a method of fabricating a non-volatile memory according to embodiments of the present invention. As illustrated in FIG. 4, a number of shallow trench isolation (STI) structures, 410 and 412, are formed in a silicon substrate 405. Twin-wells are formed in subsequent processing steps. As will be described in more detail below, the two different regions in FIG. 4 are used for TwinMONOS storage transistors and control gate stitches. In some embodiments, threshold voltage (V_{T}) adjustments and punch-thru implants are provided, although this is not required by the present invention. One of ordinary skill in the art would recognize many variations, modifications, and alternatives.

As further illustrated in FIG. 4, the peripheral gate oxide 430 and the cell word gate polysilicon 420 are thermally grown. The peripheral gate oxide 430 is formed utilizing methods well known to one of skill in the art. In an embodiment according to the present invention, an undoped polysilicon (poly) layer 420 is deposited to a predetermined thickness. In some embodiments, the thickness of the undoped poly layer 420, ranges from about 1,500 Å to about 2,500 Å. In alternative embodiments, other thicknesses are utilized as appropriate to the particular application. With a non-critical masking step, the poly layer is doped to form n⁺ regions in cell and peripheral NMOS regions.

A peripheral cap oxide (not shown) is subsequently deposited and patterned. According to some embodiments, the peripheral cap oxide is deposited with a predetermined thickness, for example, a thickness ranging from about 100 Å to about 400 ÅIn the embodiment illustrated in FIG. 4, a cell cap nitride 422 is deposited over the undoped poly layer. The cell cap nitride 422 is deposited with a predetermined thickness. In some embodiments, the thickness of layer 422 ranges from about 200 Å to about 400 Å. As will be evident to one of skill in the art, the thicknesses of these layers, as well as other layers discussed throughout the specification, depend on the particular applications provided by embodiments of the present invention. Moreover, the materials selected, such as a peripheral cap oxide or a cell cap nitride will depend on the particular application.

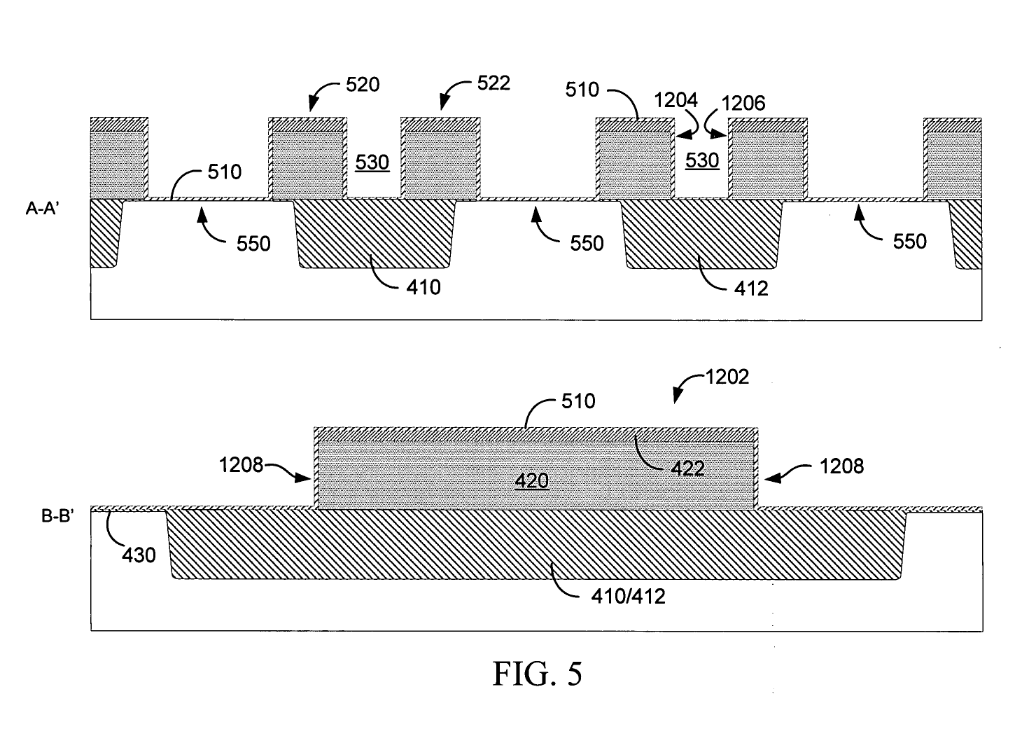

The fabrication process is continued, as illustrated in FIG. 5, as the word gate photolithography and etch are performed, stopping on the gate oxide, which is subsequently removed as described below. In some embodiments, the etch is a reactive ion etch (RIE) process, although this is not required by the present invention. Word gates 520 and 522 are formed during the photolithography and etching steps on opposite sides of word gate slots 530. As illustrated in FIG. 5, word gates associated with each of the STI regions 410/412 are provided according to embodiments of the present invention. In an embodiment, the gate oxide is removed as illustrated in region 550 using a buffered HF etch and an oxide-nitride-oxide (ONO) stack 510 is grown or deposited on the substrate.

Referring to the B-B′ cross-section along the CG direction as illustrated in FIG. 5, the gate oxide in region 430 is also removed in the structure. As illustrated, the ONO stack is a conformal composite layer, covering the exposed sides of the word gates as well as the undoped poly 420 and cell cap nitride 422 illustrated in the B-B′ cross-section.

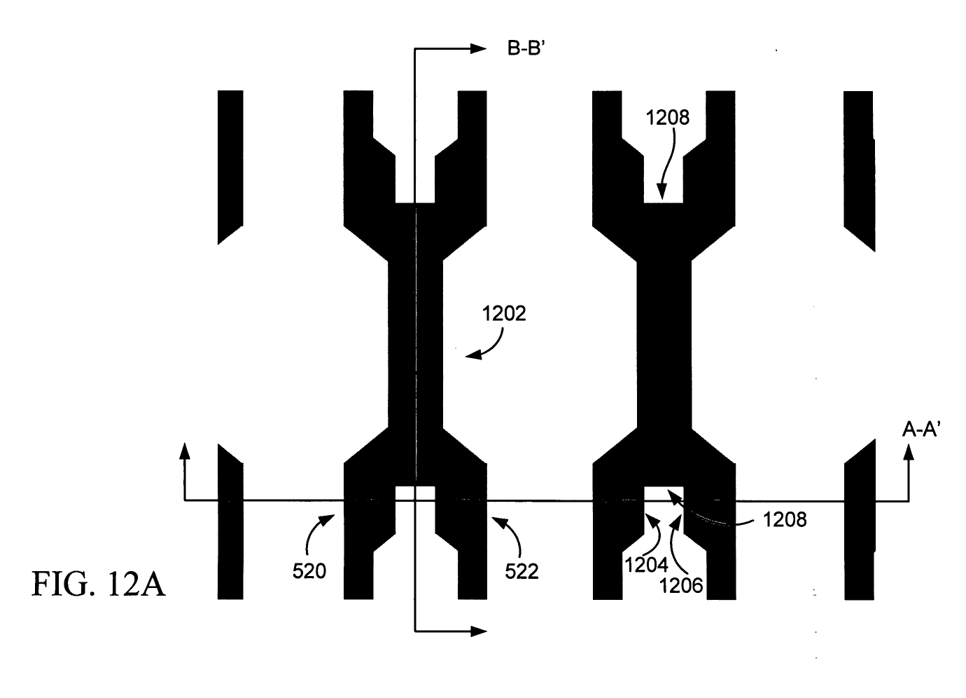

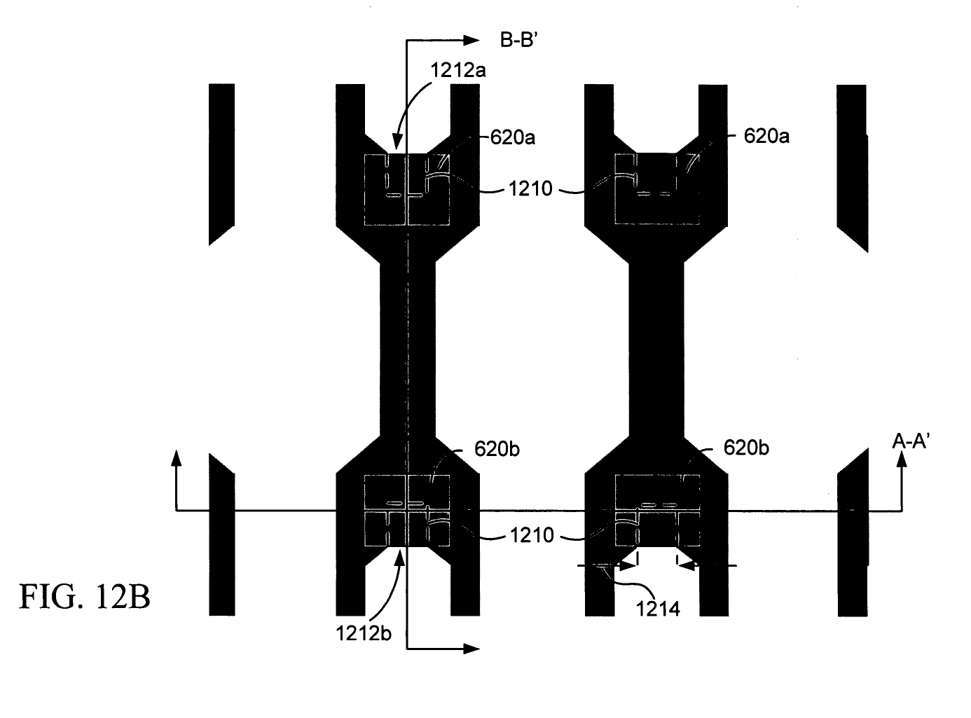

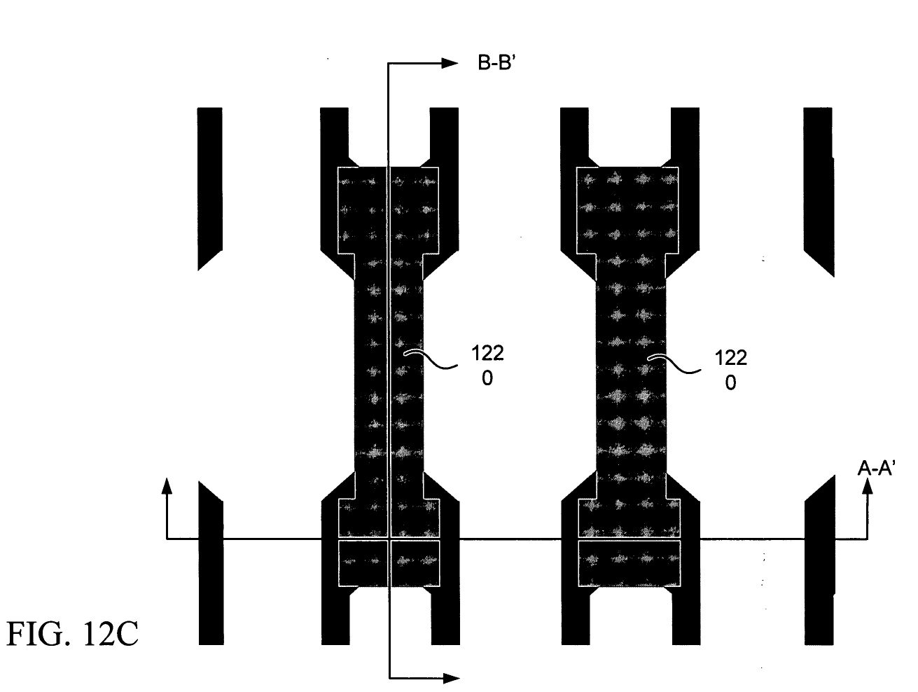

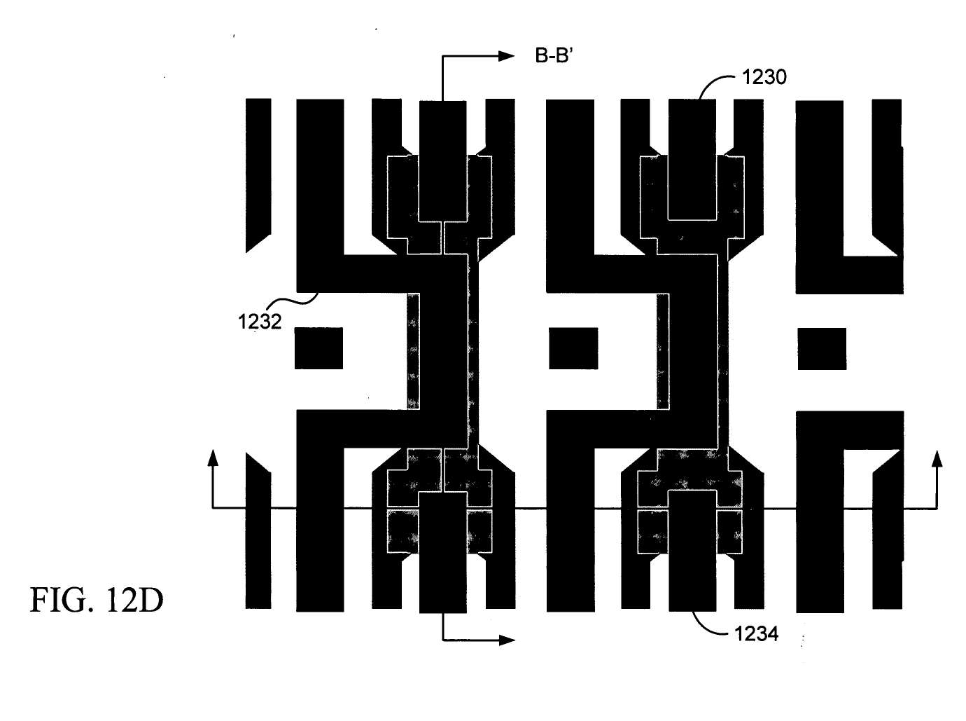

FIG. 12A is a simplified top view diagram illustrating various layers of a memory array according to an embodiment of the present invention. As illustrated in FIG. 12A, the layers processed as illustrated in FIG. 5 are presented in a top view. The ONO stack layers are the top layers covering the word gates 520 and 522 and are illustrated along the direction A-A′. Along direction B-B′, the word gate poly region 1202, including the pre-doped poly and cap nitride layers, is illustrated. For purposes of clarity, the ONO stack layers extending along the substrate surface to the sides of the word gates and outside the patterned word gate poly and cap nitride regions, is not shown in FIG. 12A. Moreover, the STI regions illustrated in FIGS. 4 and 5 are not illustrated in FIG. 12A for purposes of clarity.

As illustrated in FIGS. 5 and 12A, the word gates in the stitch regions contain slots which include two opposing side portions 1204 and 1206. As illustrated in the figure, these opposing vertical structures are covered with the ONO stack. Additionally, as illustrated in the B-B′ cross-section, an interior portion 1208 is associated with each of the word gate structures. This vertical interior portion is also covered with the ONO stack. As described in further detail below, the three sided box formed at one end by the interior portion and on two sides by the two opposing side portions will be filled with a poly plug surrounded in the plane of the substrate on three sides.

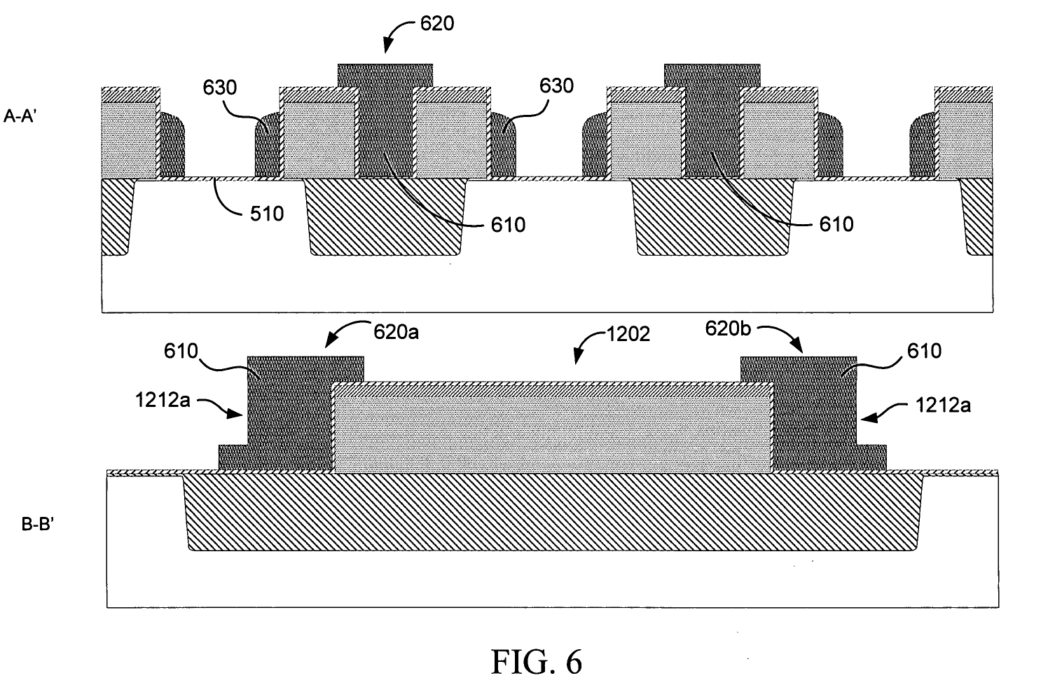

FIG. 6 illustrates the deposition and patterning of an in situ doped n⁺ polysilicon layer 610 to form a doped poly layer of a predetermined thickness. In some embodiments, the thickness of layer 610 ranges from about 400 Å to about 600 Å. Generally, the doped poly layer 610 is formed using a low pressure chemical vapor deposition (LPCVD) process, although this is not required by the present invention. One of ordinary skill in the art would recognize many variations, modifications, and alternatives. As described more fully below, and illustrated in FIG. 6, in the stitch area, polysilicon layer 610 preferably fills the word gate slot 530. A mask (not shown) is formed covering a region adjacent the word gate slots and the polysilicon layer is anisotropically etched using an RIE process to form poly plugs 620 and side-wall poly spacers 630. In the embodiment illustrated in FIG. 6, the etching of the poly layer stops upon reaching the top oxide included in the ONO stack.

FIG. 12B is a simplified top view diagram illustrating various layers of a memory array according to an embodiment of the present invention. As illustrated in FIG. 12B, the layers processed as illustrated in FIG. 6 are presented in a top view. The patterning of the polysilicon above the word gate slots to form the poly plugs 620 as shown in FIG. 6 is illustrated by square regions 620 and 620b in FIG. 12B. As illustrated by the dashed lines 1210, the poly plugs extend along B-B′ on both sides of the patterned word gate poly and cap nitride layers. For reference, surface 1212a and 1212b are shown in FIGS. 6 and 12B to illustrate the position of the poly plugs on both sides of the word gate poly region 1202. For purposes of clarity, the side-wall poly spacers are not illustrated in FIG. 12B.

In some embodiments of the present invention, the patterned poly layer filling and adjacent to the word gate slots 530 are referred to as poly plugs. Referring to FIG. 12B, these poly plugs 620 are not formed in a recessed region surrounded on four sides by solid material, which is an architecture generally associated with via plugs and other gapfill processes well known in semiconductor processing. As illustrated in FIGS. 6 and 12B, the poly plugs provided by embodiments of the present invention are surrounded on three sides by the ONO stack 510 present on the lateral outer surfaces of the word gate poly region 1202. Dashed lines 1210 represent a top-view of the vertical surfaces contacting the poly plug formed according to embodiments of the present invention. In the fourth direction, illustrated by surfaces 1212a and 1212b in FIGS. 6 and 12B, the poly plug is not surrounded by the ONO stack, but forms an exposed surface at the processing stage illustrated in FIG. 6. In an embodiment, the poly plugs are formed between at least one of the word gate structures.

Referring to FIG. 12B, some embodiments of the present invention utilize a word gate slot 530 with a width 1214, which is a preselected distance. In an embodiment, the width 1214 of the WG slot is less than or equal to 0.16 μm. The slot width can be adjusted according to the technology node and the thickness of the CG poly. Utilizing this narrow geometry, CGs fabricated along the word gates are joined in regions 1210, enabling a single poly plug 620 to simultaneously provide electrical contact to two adjacent CGs.

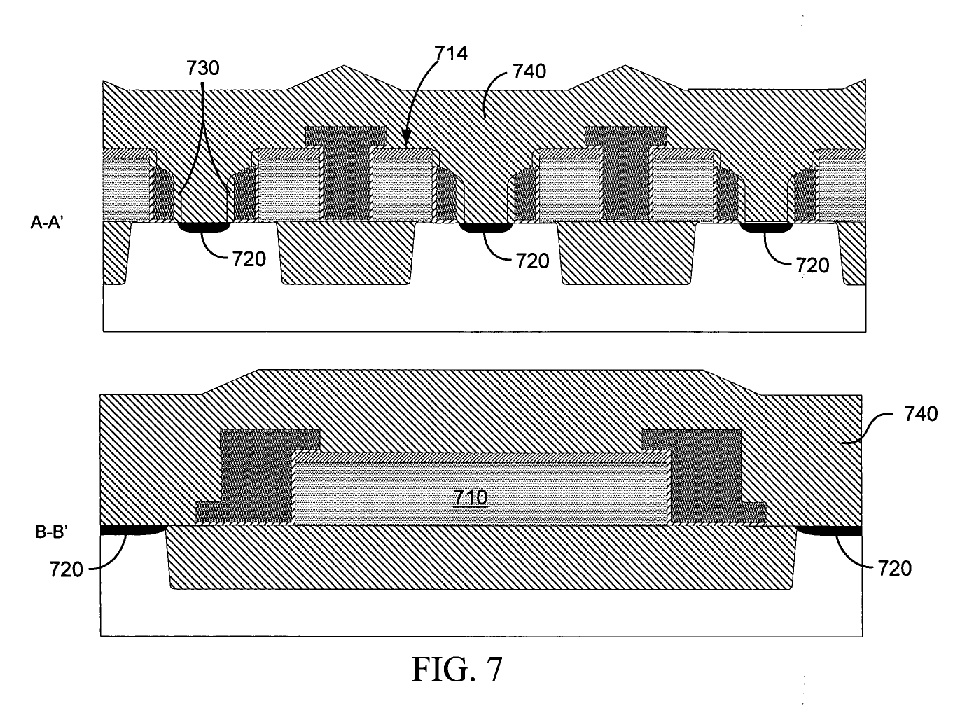

In FIG. 7, an etching process, for example, an RIE process, is used to remove the ONO stack from the tops of the WGs as illustrated by reference number 714 and in regions where BLs 720 are to be fabricated as described more fully below. In some embodiments, the RIE process is terminated on the bottom oxide in the ONO stack. An oxide layer, preferably a high-temperature oxide, is formed and patterned to produce oxide spacers 730 on the sides of the side-wall poly spacers and adjacent the bit lines as illustrated in cross-section A-A′. As illustrated in FIG. 7, bit lines 720 are implanted in regions where the ONO stack was removed in previous processing steps. In the embodiment illustrated in FIG. 7, an implantation/diffusion process, generally using phosphorous or arsenic followed by high temperature diffusion, is performed to produce bit lines 720. In an embodiment, after formation of the bit lines using the implantation/diffusion process, a high-density plasma chemical vapor deposition (HDP-CVD) process is utilized to form oxide layer 740. In an embodiment, the oxide layer 740 covers the previously formed poly plugs.

Examples of HDP-CVD systems include inductively-coupled plasma systems and electron cyclotron resonance (ECR) plasma systems among others. HDP-CVD systems generally operate at lower pressure ranges than low density plasma systems. The low chamber pressure employed in HDP-CVD systems provides active species having a long mean-free-path and reduced angular distribution. These factors, in combination with the plasma's density, provide films with improved gap-fill capabilities as compared to films deposited in a low density plasma CVD system. Additionally, the simultaneous occurrence of deposition and sputtering promoted by the plasma's high density further serves to improve the gap-fill capabilities of HDP-CVD systems.

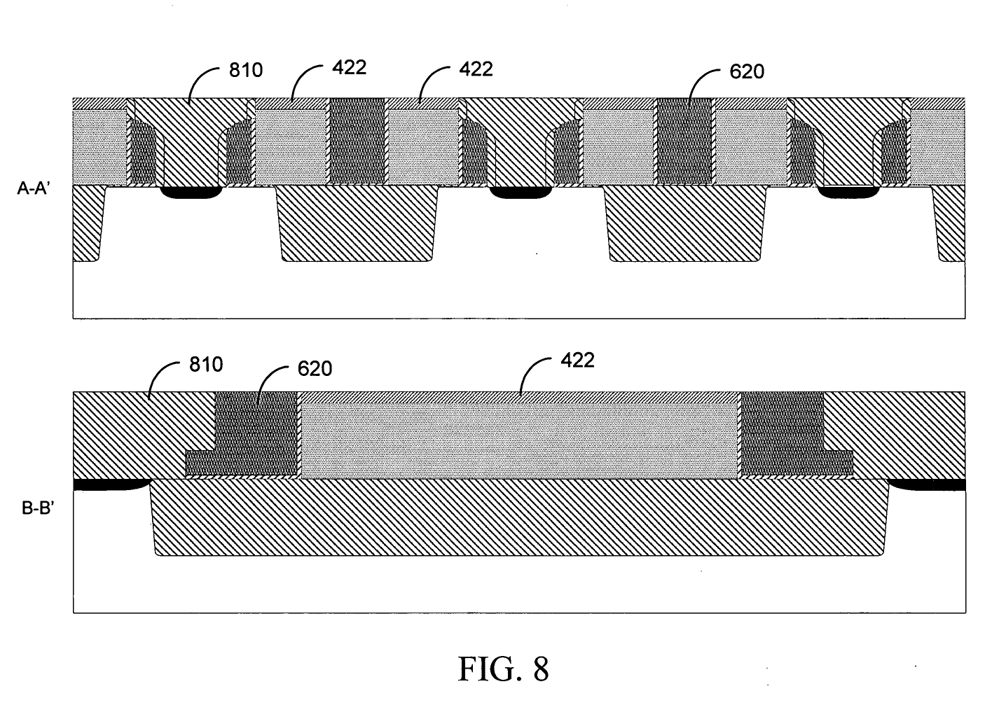

As illustrated in FIG. 7, the surface morphology present after the HDP-CVD process is not planar. Although planar surfaces following deposition are included within the scope of the present invention, layers deposited over patterned substrates typically possess a degree of non-planarity as illustrated in FIG. 7. To provide a planar surface, a chemical mechanical polishing (CMP) process is performed as illustrated in FIG. 8, to planarize the bit line HDP oxide 810. In the embodiment of the present invention illustrated in FIG. 8, the CMP process is terminated upon reaching silicon nitride layer 422. As will be evident with reference to FIG. 4, silicon nitride layer 422 was originally deposited on the gate poly and referred to as cell cap nitride 422. As illustrated in FIG. 8, the CMP process exposes the poly plugs 620.

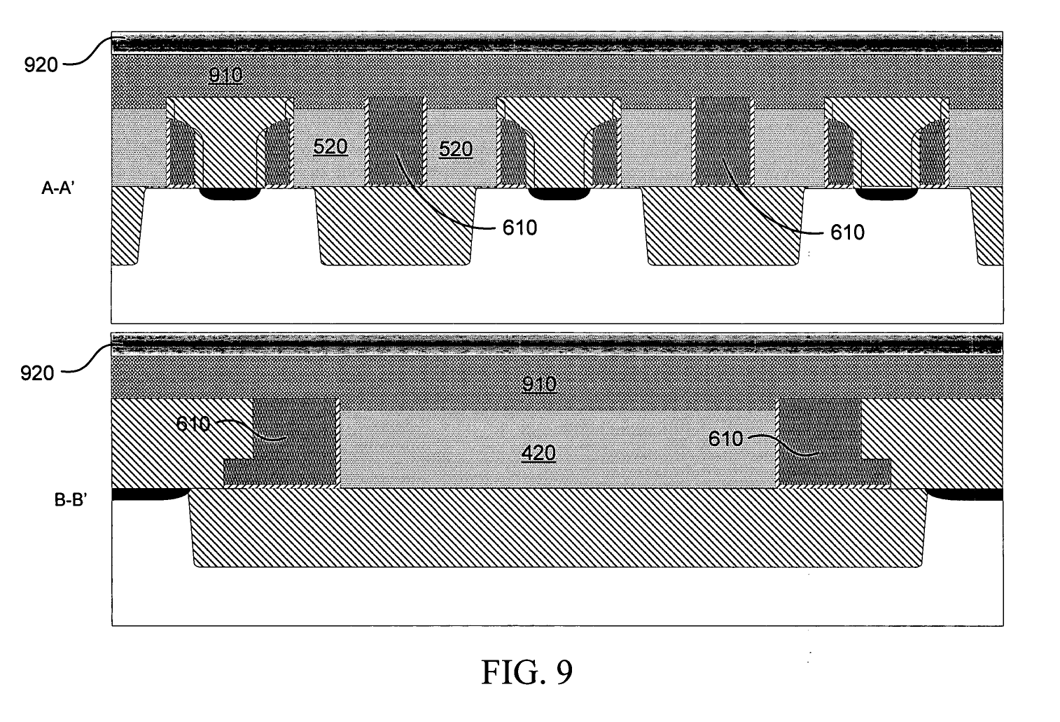

The silicon nitride layer 422 is removed as illustrated in FIG. 9. In some embodiments, the silicon nitride cap layer is removed using a wet chemistry process, although this is not required by the present invention. After removal of the silicon nitride layer, a CVD polysilicon layer 910 is conformally deposited at a predetermined thickness. According to embodiments of the present invention, the thickness of the CVD poly layer 910 ranges from about 1,000 Å to about 3,000 Å. In alternative embodiments, the thickness of the CVD poly layer varies depending on the particular application.

In some embodiments of the present invention, polysilicon layer 910 is deposited using an in situ doping process. In other embodiments, POC1₃ doping and ion implantation processes are utilized to form layer 910. As will be evident to one of skill in the art, embodiments of the present invention are not limited to these particular deposition and/or doping processes. As will be described more fully below, poly layer 910 is utilized in embodiments of the present invention as the word line poly. As illustrated in FIG. 9, the CVD poly layer 910 makes electrical contact with the word gate poly 420. Additionally, the CVD poly layer 910 makes electrical contact with the control gate poly plug 610. A tungsten silicide layer 920 is deposited on the polysilicon layer 910. Various deposition processes are utilized in embodiments of the present invention to form the tungsten silicide layer 920 as will be evident to one of skill in the art. Merely by way of example, CVD or physical vapor deposition (PVD) processes are utilized in various embodiments of the present invention.

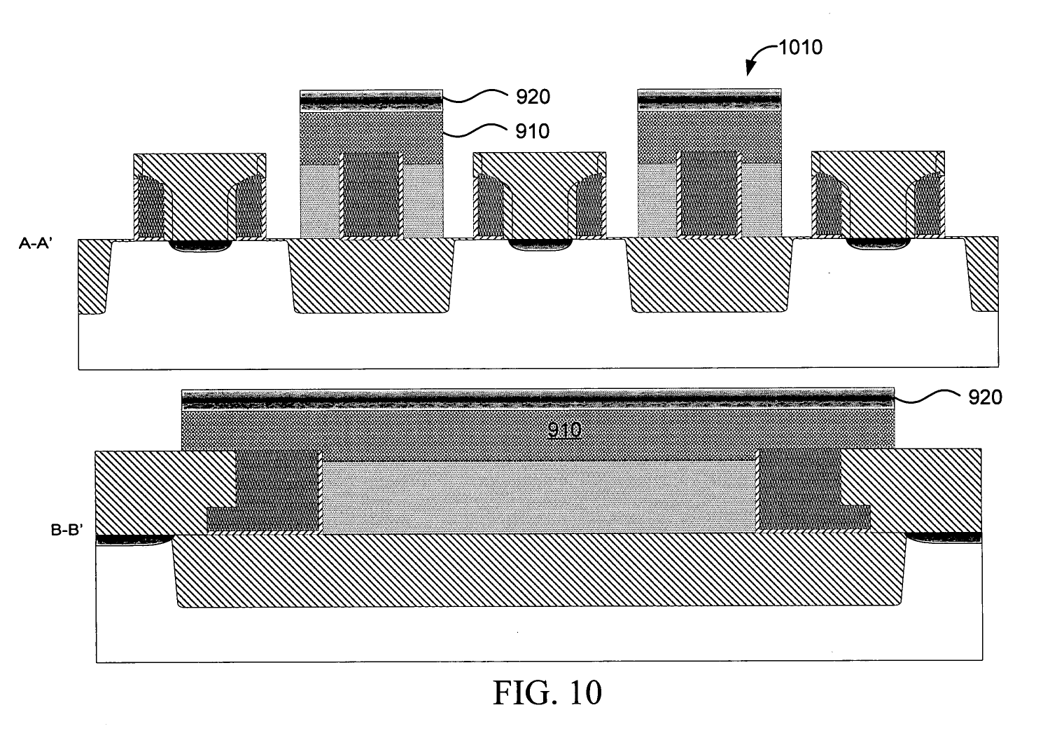

FIG. 10 illustrates another stage of a fabrication process for a memory array according to an embodiment of the present invention. As illustrated in FIG. 10, photolithography and etching processes are performed to remove portions of the polysilicon layer 910 and the tungsten silicide layer 920. In the embodiment of the present invention illustrated in FIG. 10, a self aligned etch is used to define the word line poly in the stitch area represented in both cross-sections. Although not illustrated in these figures, peripheral transistor processing is performed following the processing steps illustrated in FIG. 10.

FIG. 12C is a simplified top view diagram illustrating various layers of a memory array according to an embodiment of the present invention. As illustrated in FIG. 12C, the layers processed as illustrated in FIG. 10 are presented in a top view. The upper surface of the tungsten silicide layer 920 is illustrated by dumb-bell shaped features 1220 in FIG. 12C. Along the direction A-A′, word line poly regions 1220 are positioned over the word gate slot, but with a smaller dimension along A-A′ than the distance between adjacent control gates 630 (see FIG. 6). Along the dimension B-B′, the regions 1220 extends over the ends of the n⁺ poly 610 and the intersection of the n⁺ poly 610 and the HDP oxide layer 810 (see FIG. 8). As illustrated in FIG. 10, the word line poly regions are generally formed as a dual layer poly/W silicide structure. One of ordinary skill in the art would recognize many variations, modifications, and alternatives.

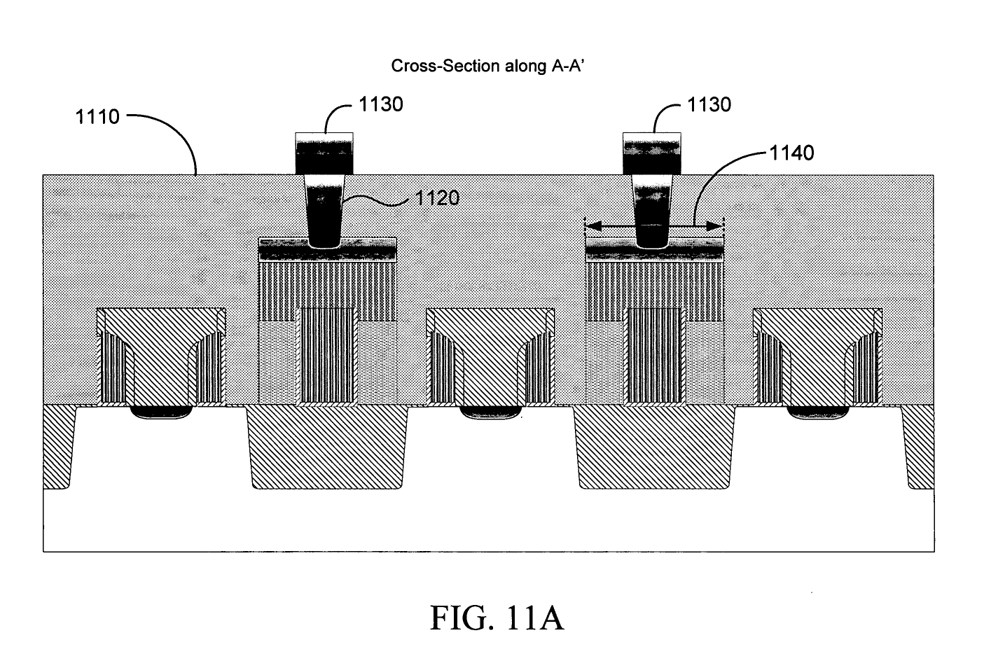

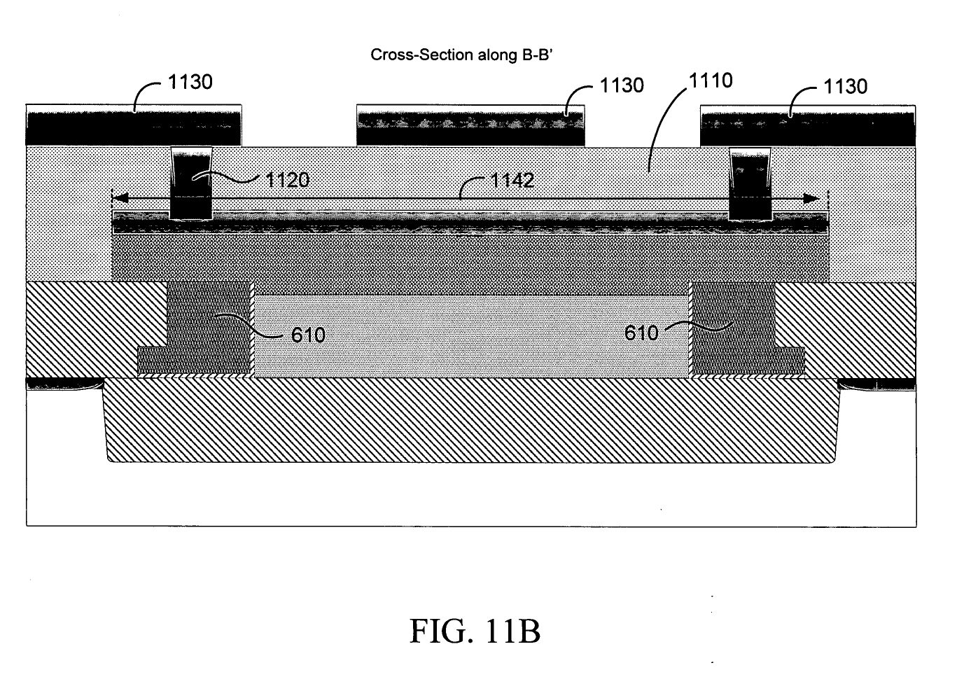

FIGS. 11A and 11B are simplified cross-sectional view diagrams of a resulting structure according to an embodiment of the present invention. In the embodiment illustrated in FIGS. 11A and 11B, interlevel dielectric (ILD) layer 1110 is deposited and planarized using a CMP process. In a specific embodiment, the ILD layer is a layer comprising oxide, nitride, combinations thereof, and the like. Contact openings 1120 are formed using a photolithography and etching process and subsequently filled with contact material. Via plug formation and fill processes well known to one of skill in the art are utilized according to some embodiments of the present invention. In the embodiment illustrated in FIG. 11A, the contact material is tungsten, although this particular contact material is not required by the present invention. Alternative embodiments utilize polysilicon as a contact material. One of ordinary skill in the art would recognize many variations, modifications, and alternatives.

Metal interconnect 1130, generally referred to as the metal-1 layer (M1), is formed using processes well known to one of skill in the art. Additional metal interconnect layers as well as passivation layers (not shown) are formed in subsequent processing steps to complete the semiconductor process. Control gates 610 are illustrated in FIG. 11B as positioned below contacts 1120. As illustrated in FIG. 11B, the interlevel dielectric layer 1130, contacts 1120, and metal-1 layer 1130 are also formed in the cross-section along B-B′.

In embodiments of the present invention, the stitch area is defined by the product of the width 1140 along the word line metallization in the A-A′ direction as illustrated in FIG. 11A and the length 1142 along the word line metallization in the B-B′ direction as illustrated in FIG. 11B. Utilizing embodiments of the present invention, the size of the stitch area is reduced, in some embodiments, by up to and exceeding 25%.

FIG. 12D is a simplified top view diagram illustrating various layers of a memory array according to an embodiment of the present invention. As illustrated in FIG. 12D, the structure resulting from processing operations as illustrated in FIGS. 11A and 11B are presented in a top view. The upper surface of the metal-1 is illustrated by features 1230 and 1232 in FIG. 12D. Along direction B-B′, M−1 lines 1230 and 1234 are strapped by the word line poly. For purposes of clarity, the vias filled by tungsten plugs 1120 are not illustrated in FIG. 12D.

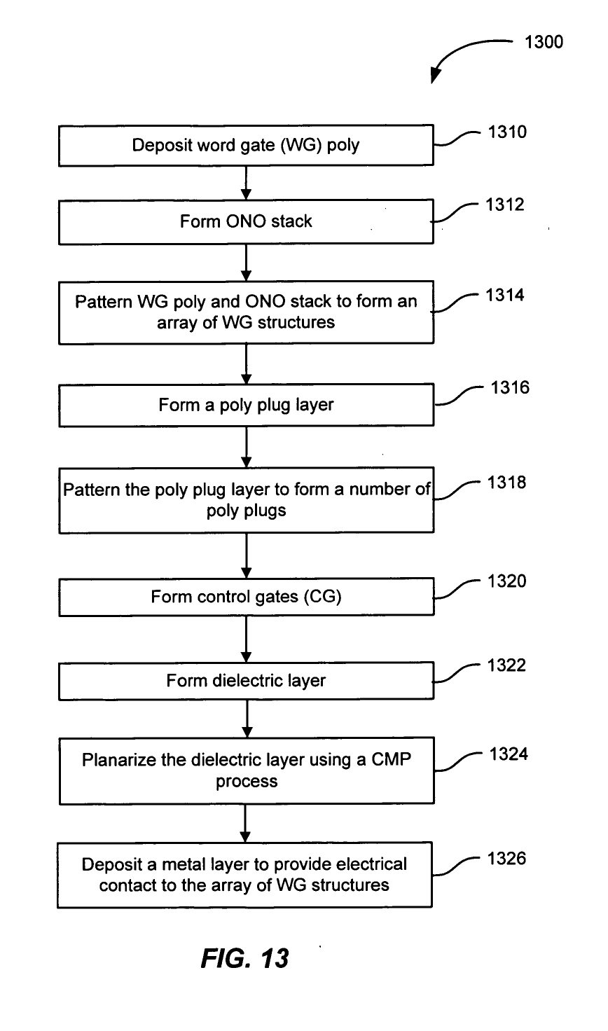

FIG. 13 is a simplified flow diagram illustrating a method of fabricating a memory array according to an embodiment of the present invention. In the method 1300 illustrated in FIG. 13, a word gate poly is deposited on a substrate (1310). An ONO layer is formed in contact with the word gate poly (1312), for example as an ONO stack that is deposited on top of the word gate poly. The word gate word gate poly layer and the ONO layer are patterned (1314) to form an array of word gate structures.

A poly plug layer is formed (1316) and patterned (1318) to form a plurality of poly plugs surrounded in the plane of the substrate on three sides. In embodiments of the present invention, the poly plugs are surrounded on three sides by the ONO stack. Control gates are formed (1320) and a dielectric layer is formed (1322). The dielectric layer is planarized using a chemical-mechanical polishing (CMP) process (1324) to form a uniform upper surface on the substrate. A metal layer is deposited (1326) to provide electrical contact to the word gate structures. Methods other than deposition are utilized in alternative embodiments to form the metal layer. One of ordinary skill in the art would recognize many variations, modifications, and alternatives.

It should be appreciated that the specific steps illustrated in FIG. 13 provide a particular processing sequence according to a specific embodiment of the present invention. Other sequence of steps may also be performed according to alternative embodiments. For example, alternative embodiments of the present invention may perform the processing steps outlined above in a different order. Moreover, the individual steps illustrated by this figure may include multiple sub-steps that may be performed in various sequences as appropriate to the individual step. For example, processing steps such as CMP processes may entail additional sub-steps not illustrated in the processing sequence discussed above. Furthermore, additional processing steps may be added or removed depending on the particular applications. One of ordinary skill in the art would recognize many variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method of manufacturing a non-volatile semiconductor memory, the method comprising:
forming a word gate poly layer on a substrate, wherein an upper surface of the substrate defines a plane of the substrate;
forming a first dielectric layer coupled to the word gate poly layer;
patterning the word gate poly layer and the first dielectric layer to form an array of word gate structures;
forming a poly plug layer and patterning the poly plug layer to form a plurality of poly plugs surrounded in the plane of the substrate on three sides;
forming a plurality of control gates;
forming a second dielectric layer;
planarizing the second dielectric layer using a chemical-mechanical polishing process; and
depositing a metal layer to provide electrical contact to the word gate structures.

2. The method of claim 1 wherein forming the plurality of poly plugs and forming the plurality of control gates are performed concurrently.

3. The method of claim 2 wherein forming the plurality of poly plugs and forming the plurality of control gates are performed simultaneously.

4. The method of claim 1 wherein the word gate poly comprises polysilicon doped after deposition.

5. The method of claim 1 wherein the first dielectric layer comprises an oxide-nitride-oxide stack.

6. The method of claim 1 wherein the word gate structures comprise a plurality of word gate slots in a stitch area.

7. The method of claim 6 wherein at least one of the plurality of word gate slots is less than or equal to 0.16 μm wide.

8. The method of claim 6 wherein each of the plurality of poly plugs are formed in each of the plurality of word gate slots.

9. The method of claim 1 wherein the second dielectric layer comprises an oxide layer.

10. The method of claim 1 wherein the plurality of poly plugs comprise a first control gate from a first word line coupled to a second control gate from a second word line.

11. The method of claim 10 wherein the first word line and the second word line are associated with adjacent word lines.

12. The method of claim 10 wherein the first control gate and the second control gate are in electrical contact via a word line poly.

13. A MONOS memory array comprising:
an array of paired word gates disposed on a surface of a substrate, each of the paired word gates comprising an interior portion and two opposing side portions;
an ONO stack coupled to the array of paired word gates, the ONO stack covering the interior portion and the two opposing side portions of each of the paired word gates;
an array of word gate slots disposed between the interior portion and the two opposing side portions of the paired word gates; and
an array of poly plugs, each of the poly plugs formed in a word gate slot and coupled to the ONO stack on three sides.

14. The MONOS memory array of claim 13 wherein the three sides are the interior portion and the two opposing side portions of each of the paired word gates.

15. The MONOS memory array of claim 13 further comprising a word line coupling a first poly plug selected from the array of poly plugs to a second poly plug selected from the array of poly plugs.

16. The MONOS memory array of claim 15 wherein the word line comprises an undoped poly layer, a doped poly layer, and a tungsten silicide layer.

17. The MONOS memory array of claim 16 wherein the doped poly layer comprises an in situ doped poly layer.
